(19) United States
(12) Patent Application Publication
(10) Pub. No.: US 2015/0263232 A1
(43) Pub. Date: Sep. 17, 2015

(54) OPTICAL SEMICONDUCTOR ELEMENT

(71) Applicant: KABUSHIKI KAISHA TOSHIBA, Tokyo (JP)

(72) Inventors: Tomonari SHIODA, San Jose, CA (US); Koichi TACHIBANA, Nara Nara (JP)

(21) Appl. No.: 14/475,517

(22) Filed: Sep. 2, 2014

(30) Foreign Application Priority Data
Mar. 14, 2014 (JP) 2014-052308

(51) Int. Cl. H01L 33/24; H01S 5/343; H01L 33/06; H01L 33/32; H01L 33/00

(52) U.S. Cl. CPC H01L 33/24; H01L 33/32; H01L 33/0075; H01L 33/06; H01L 33/0025; H01S 5/34333

(57) ABSTRACT

An optical semiconductor element includes a first nitride semiconductor layer of a first conductivity type, a second nitride semiconductor layer of a second conductivity type, and an active layer provided between the first nitride semiconductor layer and the second nitride semiconductor layer. In the optical semiconductor element, a feature is provided in the active layer, and the second nitride semiconductor layer is provided within the feature of the active layer.

### CROSS-REFERENCE TO RELATED APPLICATION

This application is based upon and claims the benefit of priority from Japanese Patent Application No. 2014-052308, filed Mar. 14, 2014, the entire contents of which are incorporated herein by reference.

### FIELD

Embodiments described herein relate generally to an optical semiconductor element.

### BACKGROUND

An optical semiconductor element which uses a nitride semiconductor material and operates in a visible light region and/or in an ultraviolet region has been developed. A nitride semiconductor material comprising gallium nitride or the like is used in the optical semiconductor element. The nitride semiconductor material typically is epitaxially grown by using a Metal Organic Chemical Vapor Deposition (MOCVD) method. In order to acquire a crystal of good quality (low defects), it is preferable to use a crystal substrate having the same lattice constant as a nitride semiconductor crystal. However, such a substrate is generally expensive, and is thus not appropriate for manufacturing a consumer optical semiconductor element, for example, a lighting element, a display, or the like. A general-purpose substrate, such as a sapphire substrate, a silicon substrate, or the like is generally used for these applications. However, a generation of crystal defect caused by a lattice mismatch or a difference in thermal expansion coefficient cannot be avoided with these substrate materials.

### DESCRIPTION OF THE DRAWINGS

FIGS. 1A and 1B are schematic cross-sectional views illustrating an optical semiconductor element according to an example embodiment.

FIGS. 2A to 2C are schematic cross-sectional views illustrating a manufacturing process for forming the optical semiconductor element according to the example embodiment.

FIGS. 3A and 3B are schematic cross-sectional view illustrating a manufacturing process which follows the manufacturing process depicted in FIGS. 2A to 2C.

FIG. 4 is a schematic view illustrating a method of forming an active layer according to the example embodiment.

FIG. 5 is a transmission electron microscopy (TEM) image depicting a cross section of the optical semiconductor element according to a comparative example.

FIGS. 6A and 6B are schematic views illustrating an operation of the optical semiconductor element according to the example embodiment.

FIG. 7 is a graph illustrating properties of the optical semiconductor element according to the example embodiment.

### DETAILED DESCRIPTION

The present disclosure describes an optical semiconductor element having a high efficiency in which an impact of a crystal defect is suppressed.

In general, an optical semiconductor element (e.g., a light emitting diode or laser diode) includes a first nitride semiconductor layer of a first conductivity type (e.g., n-type) and an active layer (e.g., a light emitting layer) having a first surface disposed on the first nitride semiconductor layer and having a feature (e.g., a pit or groove) formed therein that extends from a second surface that is parallel and opposite the first surface into the active layer. A second nitride semiconductor layer of a second conductivity type (e.g., p-type) is disposed on the second surface of the active layer and has a portion filling the feature formed in the active layer. The active layer has a thickness between the first nitride semiconductor layer and the portion of the second nitride semiconductor layer that is greater than zero and less than a distance between the first and second surfaces.

In general, according to another embodiment, an optical semiconductor element includes a first nitride semiconductor layer of a first conductivity type, a second nitride semiconductor layer of a second conductivity type, and an active layer provided between the first nitride semiconductor layer and the second nitride semiconductor layer. In the optical semiconductor element, an initial point is provided on the active layer, and a pit which expands in a first direction toward the second nitride semiconductor layer from the initial point is provided.

In general, an example embodiment will be described with reference to drawings. The equivalent parts in the drawings are referenced by the same reference numerals and the detailed descriptions thereof will not be repeated. In addition, the drawings are schematic and conceptual. Any relationship between a thickness and a width of parts or elements, a size ratio between the elements, or the like is not necessarily the same as the reality. In addition, even when the same part is indicated in multiple figures, there may be cases where a dimension or a ratio is different from each other according to the drawings.

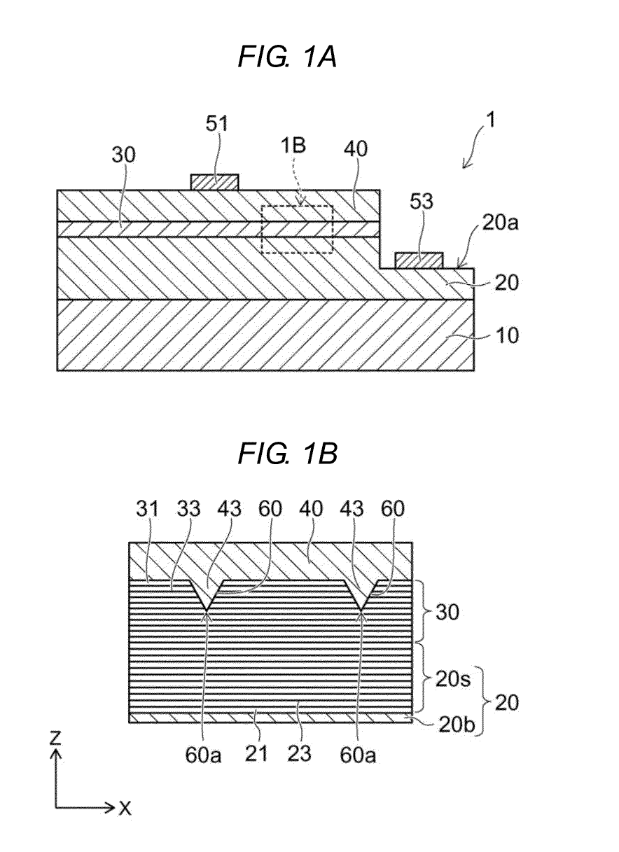

FIG. 1A is a schematic cross-sectional view illustrating an example of an optical semiconductor element 1. FIG. 1B represents a cross section which enlarges a region 1B illustrated as a dashed line in FIG. 1A.

The optical semiconductor element 1 is, for example, a light emitting diode (LED) which uses gallium nitride-based semiconductor as a material. Hereinafter, an example of the optical semiconductor element 1 will be described. However, the present disclosure is not limited thereto. For example, the optical semiconductor element 1 may be a laser diode which uses a nitride semiconductor as a material or a light-receiving element. According to the present disclosure, in a light-emitting element, such as the LED and the laser diode, it is possible to improve emission efficiency by incorporation of the described features. In addition, in the light-receiving element, it is possible to reduce a leak current, a so-called dark current, and to improve the light receiving sensitivity. In addition, the present disclosure is not limited to a specific structure of the optical semiconductor element, and the scope of the present disclosure includes a semiconductor wafer for making the optical semiconductor element, a lighting device which uses the optical semiconductor element, a manufacturing method for the optical semiconductor element, or even a crystal growth device.

The optical semiconductor element 1 illustrated in FIGS. 1A and 1B includes a first nitride semiconductor layer (hereinafter, referred to as an n-type layer 20) of a first conductivity type, an active layer 30, and a second nitride semiconductor layer (hereinafter, referred to as a p-type layer 40) of a second conductivity type. The active layer 30 is provided between the n-type layer 20 and the p-type layer 40.

Here, the first conductivity type is described as an n type, and the second conductivity type is described as a p type. However, the embodiment is not limited thereto. In other words, the first conductivity type may be described as the p type, and the second conductivity type may be described as the n type.

As illustrated in FIG. 1, the n-type layer 20 is provided on a substrate 10. The active layer 30 is provided on the n-type layer 20, and the p-type layer 40 is provided on the active layer 30.

The substrate 10 is, for example, a sapphire substrate or a silicon substrate. The sapphire substrate is transparent with respect to a visible light and an ultraviolet light, and the n-type layer 20 can be formed directly thereon or a buffer layer (not specifically depicted) may be formed between the sapphire substrate and the n-type layer 20.

The silicon substrate absorbs visible light and ultraviolet light. Here, when the silicon substrate is used as the substrate 10, it is desirable that a reflection layer be provided between the silicon substrate and the n-type layer 20. The reflection layer reflects a light radiated from the active layer 30 in a direction of the p-type layer 40, and thus improves the overall output efficiency of the optical semiconductor element 1.

The n-type layer 20 is, for example, an n-type gallium nitride (GaN) layer. The p-type layer 40 is, for example, a p-type GaN layer. The p-type layer 40 may have, for example, a p-type AlGaN in a portion which is in contact with the active layer 30. The p-type AlGaN may be a material of which a bandgap energy is larger than that of a barrier layer 33, and may be AlInGaN or InAlN.

A p-electrode 51 is provided on the p-type layer 40. The p-type layer 40 and the active layer 30 are selectively etched, and an n-electrode 53 is provided on a portion 20a which exposes the n-type layer 20. In the optical semiconductor element 1, a voltage is applied between the p-electrode 51 and the n-electrode 53, and a current flows to the active layer 30. Accordingly, the active layer 30 emits light, and the light radiates to the outside.

As illustrated in FIG. 1B, the active layer 30 has a first barrier layer (hereinafter, referred to as a barrier layer 31) and a first well layer (hereinafter, referred to as a well layer 33). The barrier layer 31 is laminated in a first direction (hereinafter, referred to as a Z direction) toward the p-type layer 40 from the n-type layer 20. The well layer 33 is provided between each of a plurality of barrier layers 31 (e.g., between a first barrier layer 31 and a second barrier layer 31).

The barrier layers 31 are, for example, a GaN layer. The well layer 33 is, for example, InₓGa₁₋ₓN (0<x≦1) layer. In a case of the well layer 33, an indium (In) composition and a film thickness of the well layer is controlled such that light with a desired wavelength is emitted. For example, when light having a wavelength of 450 nm is emitted from the active layer 30, an In ratio x is equal to 0.15. A thickness of the well layer 33 in the Z direction is, for example, 2 nm to 5 nm. Meanwhile, a thickness of the barrier layers 31 in the Z direction is, for example, 2 nm to 20 nm.

Furthermore, the active layer 30 has a plurality of pits 60. The pit 60 has an initial point 60a inside the active layer 30, that is the pit 60 does not breach the complete thickness of active layer 30 but rather the initial point 60a is at level within the active layer 30. Pit 60 is provided in a shape that expands outward (in direction(s) perpendicular to the z-direction) from the initial point 60a along the Z direction toward the p-type layer 40. The p-type layer 40 has a portion 43 which extends into and fills the inside of the pit 60.

As depicted, the pit 60 is a so-called V pit. The pit 60 has a facet (crystal face) on a side surface thereof, and has a shape of a hexagonal cone in which the initial point 60a is a peak point. According to conditions of a forming process, the pit 60 has a shape of a cone. The pit 60 may have a recessed-shape structure derived from a threading dislocation.

The active layer 30 is not limited to the example illustrated in FIG. 1B, and may have at least one well layer 33. In other words, the active layer 30 has the two barrier layers 31 laminated to each other in the Z direction with the well layer 33 provided between the two barrier layers 31. Here, the pit 60 is formed to penetrate one well layer 33.

In addition, as illustrated in FIG. 1B, the n-type layer 20 may have a second barrier layer (hereinafter, referred to as a barrier layer 21) and a second well layer (hereinafter, referred to as a well layer 23). The barrier layer 21 is, for example, laminated in the Z direction. The well layer 23 is provided between each of a plurality of barrier layers 21 (e.g., between a first (third) barrier 21 and a second (fourth) barrier layer 21).

A region in the n-type layer 20 where the barrier layer 21 and the well layer 23 are included is a superlattice layer 20s. The superlattice layer 20s is provided, for example, on an n-type GaN layer 20b. The superlattice layer 20s is provided to have an intermediate lattice constant that is between a lattice constant of the n-type GaN layer 20b and a lattice constant of the active layer 30. In other words, the superlattice layer 20s mitigates a distortion caused by a difference between the lattice constant of the n-type GaN layer 20b and the lattice constant of the active layer 30. Accordingly, it is possible to reduce a piezoelectric field caused by a distortion generated on the active layer 30, and to improve optical properties. In addition, it is possible to reduce a misfit dislocation generated on the active layer 30.

In addition, the “lattice constants” of the active layer 30 and the superlattice layer 20s referred to here are average lattice constants which are calculated, for example, from the thicknesses of the barrier layer and the well layer, and the lattice constants of the barrier layer and the well layer.

The barrier layer 21 is, for example, a GaN layer. The well layer 23 is, for example, a In_{y}Ga_{1-y}N (0<y<1) layer. A ratio y of the indium included in the well layer 23 is, for example, 0.01 to 0.1. The thickness of the well layer 23 in the Z direction is, for example, 1 nm to 3 nm. Meanwhile, the thickness of the barrier layer 21 in the Z direction is, for example, 1 nm to 10 nm. The barrier layer 21 and the well layer 23 may have an n-type impurity, such as Si, in some embodiments.

In addition, in a case of the light-emitting element, it is preferable that the bandgap of the well layer 23 in the superlattice layer 20s be wider than the bandgap of the well layer 33 in the active layer 30. Accordingly, it is possible to suppress the absorption in the superlattice layer 20s of the light emitted from the active layer 30. In other words, it is preferable that a content ratio y of the indium included in the well layer 23 of the superlattice layer 20s be smaller than a content ratio x of the indium included in the well layer 33 of the active layer 30. It is preferable that the bandgap energy in a quantum well structure be mainly specified by the bandgap energy and a width of the well of the well layer 33, and that the bandgap energy included in the superlattice layer 20s as a quantum structure be larger than the bandgap energy of the active layer 30. In addition, according to such a configuration, the average lattice constant of the superlattice layer 20s is a value between the average lattice constant of the n-type GaN layer 20b and the average lattice constant of the active layer 30. Accordingly, it is possible to obtain an effect of absorbing the distortion for the active layer 30.

The active layer 30 according to the embodiment includes the well layer 33 adjusted with a range to radiate the light with the desired wavelength. The desired wavelength is, for example a light-emitting wavelength obtained in the final use. For example, the desired wavelength is the light-emitting wavelength of the light obtained by injecting 350 mA of current. According to a driving condition, there is a case where the light-emitting wavelength is slightly varied even in the same configuration condition. If a range of the light-emitting wavelength is in a range of ±5 nm from the desired light-emitting wavelength, it is possible to consider that the light is emitted from the active layer 30 in the embodiment. In an example illustrated in FIG. 1B, a boundary between the n-type layer 20 and the active layer 30 is, for example, a boundary between the well layer 23 and the barrier layer 21 which are the nearest to the active layer 30 in the superlattice layer 20s. In other words, both of the barrier layers 21 of the superlattice layer 20s and the barrier layers 31 of the active layer 30 are GaN layers. The barrier layers 21 and the barrier layers 31 which are located between the superlattice layer 20s and the active layer 30 are substantially integrated. Therefore, it is appropriate to set an interface between the barrier layer 21 and the well layer 23 which are at the nearest position to the active layer 30, to a boundary of the n-type layer 20 side. Meanwhile, it is possible to set a boundary of the p-type layer 40 side of the active layer 30, for example, to an interface of the barrier layers 31 and the well layer 33 which are the nearest to the p-type layer 40.

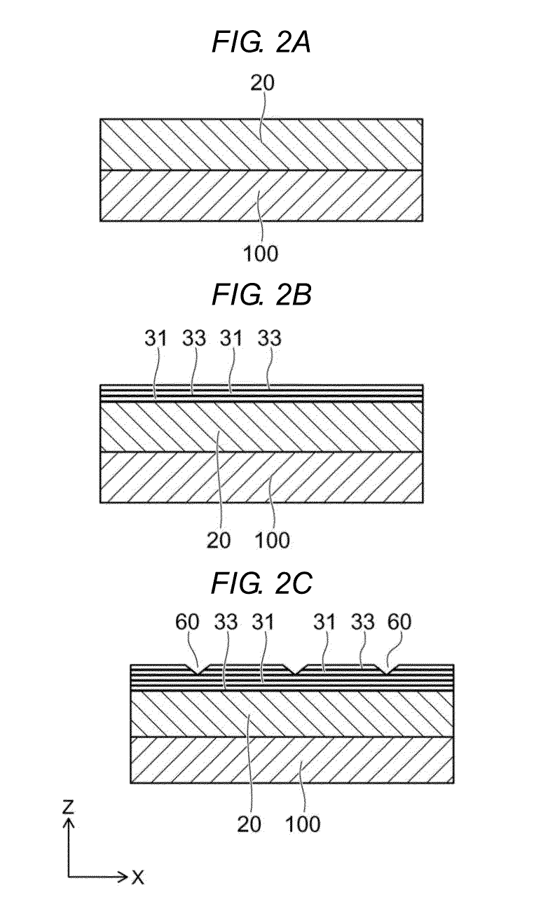

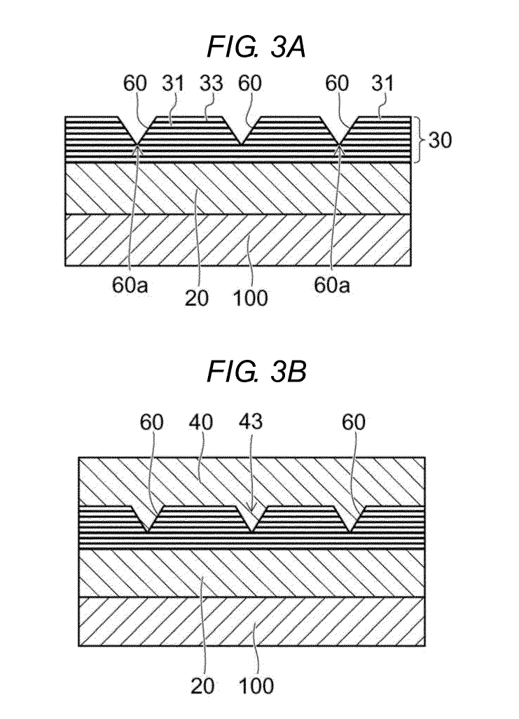

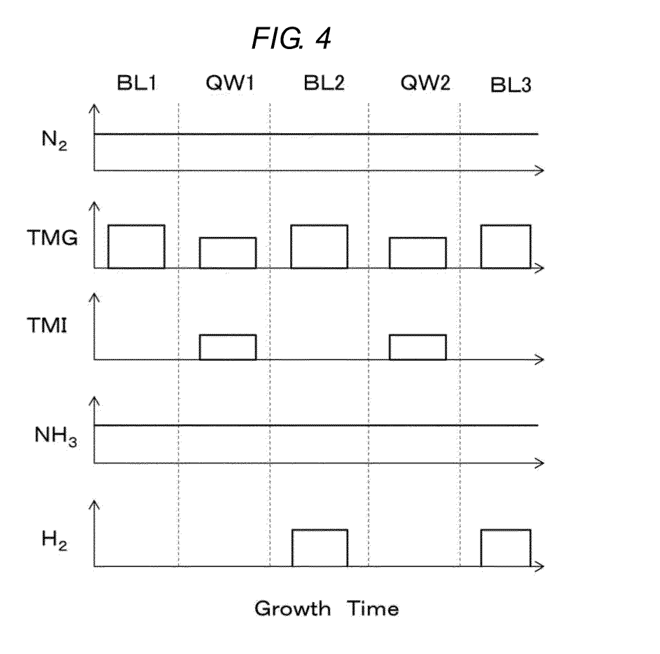

Next, with reference to FIGS. 2A to 4, a manufacturing method of the optical semiconductor element according to the embodiment will be described. FIGS. 2A to 3B are schematic cross-sectional views illustrating an example of a manufacturing process of the optical semiconductor element according to the embodiment. FIG. 4 is a schematic view illustrating an example of the forming method of the active layer according to the embodiment.

As illustrated in FIG. 2A, the n-type layer 20 is formed on a substrate 100. The n-type layer 20 is formed, for example, by using the MOCVD method, and has the n-type GaN layer 20b and the superlattice layer 20s (refer to FIG. 1B). The n-type GaN layer 20b is formed on the substrate 100. The superlattice layer 20s is formed on the n-type GaN layer 20b.

The substrate 100 is, for example, the silicon substrate. The buffer layer (not illustrated) may be formed between the substrate 100 and the n-type layer 20. The buffer layer has a multi-layered structure including, for example, an aluminum nitride (AlN) and AlGaN. A δ-doped layer having Si or other impurities, a SiN layer, or the like, also may be included. By including these layers, it is possible to suppress a crack caused by a difference in thermal expansion coefficient between the Si and the nitride semiconductor, or the threading dislocation caused by a difference in lattice constants.

For example, while the buffer layer and the n-type layer 20 are formed on the substrate 100, a plurality of dislocations is caused by the lattice mismatch between the substrate 100 and the nitride semiconductor. These dislocations are collected to the plurality of threading dislocations and reach an upper layer. For example, on the n-type layer 20, a threading dislocation is formed which has a density of 10⁸ cm⁻² to 10¹⁰ cm⁻².

Next, the active layer 30 is formed on the n-type layer 20. For example, as illustrated in FIG. 2B, the barrier layers 31 and the well layer 33 are alternately grown. As examples thereof, the barrier layer 31 is the GaN layer, and the well layer 33 is the InGaN layer.

FIG. 4 is a schematic view illustrating a supply sequence of raw material gas introduced to a reaction chamber of the MOCVD apparatus during the forming process of the active layer 30. A horizontal axis in a plurality of charts illustrated in FIG. 4 represents growth time, and the vertical axis of the plurality of charts represents a supply amount (arbitrary unit) of each raw material gas.

Each chart is separated into growth segments BL for the barrier layers 31 and by the growth segments QW for the well layer 33. For example, nitrogen (N₂) gas which is a carrier gas and ammonium (NH₃) gas which is a group V material are supplied across all the growth segments.

In the growth segment BL, for example, trimethylgallium (TMG) and ammonia (NH₃) are supplied. Accordingly, the GaN layer is formed. Meanwhile, in the growth segment QW, the trimethylgallium (TMG), trimethylindium (TMI), and the ammonia (NH₃) are supplied. Accordingly, the InGaN layer is formed.

As illustrated in FIG. 4, the growth segments BL and the growth segments QW are alternately repeated. Accordingly, the active layer 30 is formed as alternating barrier and well layers. Furthermore, in the method, during the process of growing the active layer 30, hydrogen (H₂) gas is introduced to the reaction chamber at certain points. For example, as illustrated in FIG. 4, in a growth segment BL2, the hydrogen gas is started to be introduced. Accordingly, it is possible to start forming the pit 60. For example, it is preferable to control the hydrogen gas such that it is be supplied in the growth segment BL of the barrier layers 31 and not supplied in the growth segment of the well layer 33.

For example, as illustrated in FIG. 2C, the pit 60 is formed with the barrier layers 31 grown in the segment in which the supply of the hydrogen gas is started at a starting point. The pit 60 is formed to be expanded in the Z direction as the well layer 33 and the barrier layers 31 are laminated while the hydrogen gas is supplied again. The pit 60 may be controlled in the size thereof by the flow rate of the hydrogen gas, for example. The hydrogen gas has an insignificant etching effect, and has an effect of suppressing the growth/deposition to the facet. For example, as the flow rate of the hydrogen gas increases, it is possible to suppress the growth to the facet, and to prevent the filing of the inside of the pit. Accordingly, it is possible to largely open the pit 60 in a vertical direction of the Z direction even as a laminated film thickness increases.

In addition, according to a timing of when the hydrogen gas is started to be introduced to the inside of the active layer 30, it is possible to change the starting point of the pit. For example, as illustrated in FIG. 4, as the hydrogen gas is supplied from the growth segment BL2, it is possible to set the second barrier layer as a starting point of the pit formation. An example in which the pit is formed from the interface between the barrier layers 31 and the well layer 33 is illustrated in the FIGS. 3A and 3B, however, the disclosure is not limited thereto. For example, as the hydrogen gas is introduced in the middle of the forming process of the barrier layers 31, it is possible to set a middle point of the barrier layers 31 as a starting point of the pit 60. In addition, after the process of forming the barrier layers 31 while supplying the hydrogen gas, by including a process of forming the barrier layers 31 without supplying the hydrogen gas again, it is possible to fill the pit 60, and to control the size of the pit.

Next, as illustrated in FIG. 3A, a final barrier layer 31 is grown and the formation of the active layer 30 is completed. Accordingly, it is possible to have the starting point in the middle of the active layer 30, and to form the pit 60. The initial point 60a of the pit 60 corresponds, for example, to a position of the threading dislocation which reaches the active layer 30 from the n-type layer 20.

Next, as illustrated in FIG. 3B, the p-type layer 40 is formed on the active layer 30. It is preferable that the p-type layer 40 is formed to fill (embed) the inside of the pit 60. Specifically, for example, in growing the p-type layer 40, the p-type layer 40 is grown at a higher temperature than the temperature of the active layer 30, or the supply amount of the hydrogen gas is relatively small. Accordingly, it is possible to start growth on the facet of the pit 60, to thus stop the expansion of the pit 60, and to fill the inside of the pit 60. In other words, the p-type layer 40 is formed to have the portion 43 inside of the pit 60.

It is preferable that the p-type layer 40 be formed to include, for example, the p-type AlGaN in the portion which is in contact with the active layer 30. For example, a movement of an electron to the p-type layer 40 from the active layer 30 by the p-type AlGaN is restricted, and a light-emitting recombination between the electron and a hole in the well layer 33 is promoted. Accordingly, it is possible to improve the emission efficiency of the active layer 30.

Here, the method in which the hydrogen gas is supplied in the middle of the process of growing the active layer 30 and the pit 60 is formed in the active layer 30 is illustrated. However, the disclosure is not limited to this method. For example, within the reaction chamber of the MOCVD apparatus, a number of revolutions (rotation speed) of a susceptor on which the substrate 100 mounted can be controlled, and thus it is possible to control formation of the pit 60. Specifically, when the number of revolutions of the susceptor is high, the pit 60 is not formed. When the number of revolutions is low, the pit 60 may be formed. In addition, it is possible to control the formation of the pit 60 by a growth speed of the active layer 30, a supply amount of ammonia, and the In composition.

In addition, it is possible to control the formation of the pit 60 even by the growth temperature of the well layer 33 or the barrier layer 32. For example, the higher the growth temperature is (for example, equal to or higher than 800° C. and equal to or lower than 1,150° C.), the easier the barrier layer is grown on the facet, and thus it is possible to suppress the formation of the pit 60 using elevated chamber temperatures. For example, by changing the growth temperature of layers after a certain number of layers among the plurality of barrier layers have been formed, it is possible to control the starting point of the pit 60. The formation of the pit depends on a growth speed balance between a lamination direction of the well layer 33 or the barrier layer 32 (for example, a (0001) direction when a c surface sapphire substrate or (111) silicon substrate is used), and a chemically stable facet direction (for example, (11-22)). When a growth condition is used in which the growth speed in the (0001) direction is faster than the growth speed in the (11-22) direction, the pit 60 is expanded. When a growth condition is used in which the growth speed in the (0001) direction is slower than the growth speed in the (11-22) direction, the pit 60 is grown to be embedded. By appropriately selecting such conditions for each layer, it is possible to form the light-emitting element as described.

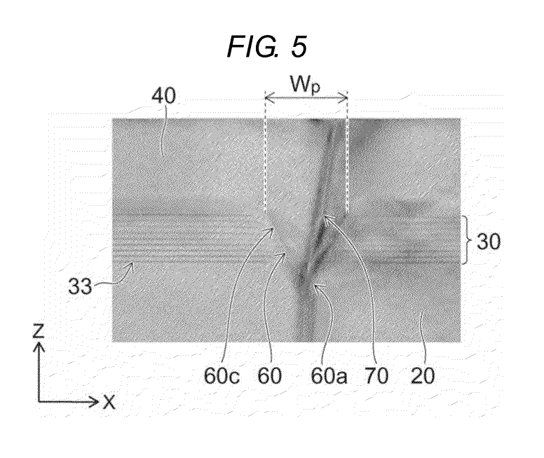

FIG. 5 is a TEM image illustrating an example of a cross section of an optical semiconductor element according to a comparative example.

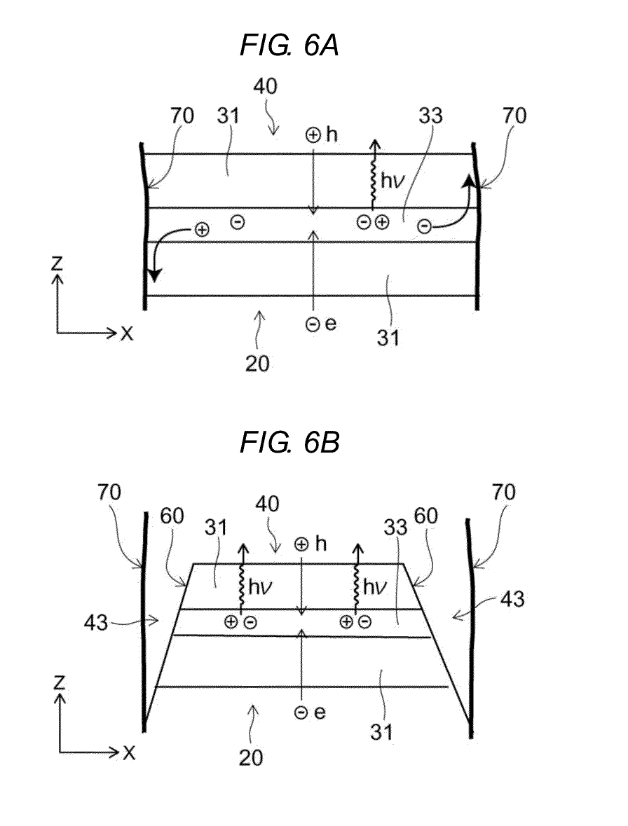

FIGS. 6A and 6B are schematic views illustrating an example of an operation of the optical semiconductor element 1.

In the example illustrated in FIG. 5, the active layer 30 is formed on the n-type layer 20, and the p-type layer 40 is formed on the active layer 30. The active layer 30 includes a plurality of well layers 33. The pit 60 is formed so as to fully penetrate the active layer 30.

In the comparative example, the initial point 60a of the pit 60 is located in the middle of the n-type layer 20. The initial point 60a may define, for example, an intersection point which extends the facet 60c of the sides of the pit 60. In addition, in the center of the pit 60, a threading dislocation 70 which reaches the p-type layer 40 from the n-type layer 20 is present. The threading dislocation 70 passes the initial point 60a of the pit 60, and is extended to the middle of the p-type layer 40.

FIG. 6A is a schematic view illustrating the cross section of the active layer 30 when the pit 60 is not formed. FIG. 6B is a schematic view illustrating the cross section of the active layer 30 when the pit 60 is formed. For simplification, an example is illustrated in which two barrier layers 31 and the well layer 33 provided between the two barrier layers 31 are included.

As illustrated in FIG. 6A, when the pit 60 is not formed, the threading dislocation 70 directly penetrates the active layer 30, and reaches the p-type layer 40 from the n-type layer 20. In such a configuration, a case may be considered in which the current flows to the active layer 30, and an electron e and a hole h are injected to the well layer 33.

In the well layer 33, the injected electron e and the hole h are recombined in a light-emitting state, and light (hv) is radiated from the active layer 30. In this example, since the active layer 30 and the threading dislocation 70 are connected with each other, a part of the electrons e and the holes h which are injected to the well layer 33 are leaked to the outside of the well layer 33 via the threading dislocation 70. In other words, in the example, a leaked current that does not contribute to the light-emitting recombination is generated. In addition, a part of the electrons e and the holes h causes non-light-emitting recombination at the threading dislocation 70, and becomes heat as a phonon, and thus a potential carrier is lost without generating light. In other words, in the comparative example, the emission efficiency is deteriorated.

In contrast to this, in the example of the FIG. 6B, the pit 60 is formed which has the threading dislocation 70 as the starting point. The example has a structure in which the portion 43 of the p-type layer 40 is interposed between the active layer 30 and the threading dislocation 70. Accordingly, it is possible to avoid the contact between the active layer 30 and the threading dislocation 70, and to suppress a current leak via the threading dislocation 70 and the non-light-emitting recombination. As a result, a likelihood of the light-emitting recombination of the electrons e and the holes h that are injected to the well layer 33 is higher, and it is possible to improve the emission efficiency of the active layer 30 such that it is higher than that of the example illustrated in FIG. 6A.

In addition, as the p-type AlGaN layer (portion of layer 40) is formed to cover the facet of the pit 60, it is possible to further enhance the above-described effect. Since the bandgap energy of the AlGaN is larger than that of the GaN, the effect to interfere the movement of the electron e is large. For this reason, as the p-type AlGaN layer is formed between the facet of the pit 60 and the threading dislocation 70, it is possible to suppress the movement of the electron e to the threading dislocation 70. In other words, it is possible to obtain a highly efficient light emission.

In such a manner, by forming the pit 60 which penetrates the full thickness of active layer 30, it is possible to reduce the leak current via the threading dislocation 70 and the non-light-emitting recombination, and to improve the emission efficiency of the active layer 30. Considering this point, for example, as illustrated in FIG. 5, the formation of the pit 60 which penetrates the entire active layer 30 is considered advantageous.

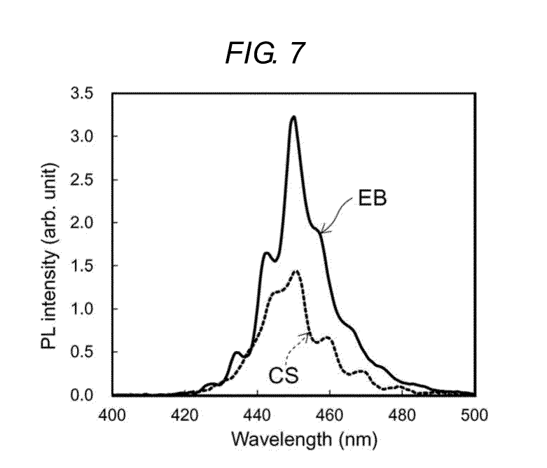

However, the pit 60 is formed such that it expands (widens) in the Z direction. For this reason, when the pit 60 is formed to be deep in the Z direction, the width W_{P} of the pit 60 on the p-type layer 40 side is also wider. As a result, for example, an area which has been cut/removed from the active layer 30 by the pit 60 is larger. As described above, the threading dislocation 70 is present at a high density of 10⁸ cm⁻² to 10¹⁰ cm⁻², for example. When a silicon is used as the substrate, as compared to a case when a sapphire is used, the difference of the lattice constant and the thermal expansion coefficient with GaN is large, and the threading dislocation is likely to be generated. For example, the threading dislocation is present at a high density of 5×10⁹ cm⁻² to 2×10¹⁰ cm⁻². A diameter in the in-plane direction of the pit is determined by a relationship between a depth of the pit and an angle of the facet. For this reason, the area of the active layer 30 is reduced at a significant level due to the pit 60. In other words, a light-emitting area of the active layer 30 is reduced, a density of the current which flows in the active layer 30 also concomitantly increases, and the emission efficiency is deteriorated. FIG. 7 is a graph illustrating the example thereof.

FIG. 7 is a graph illustrating the example of properties of the optical semiconductor element 1 according to the embodiment. A vertical axis is a photoluminescence intensity (PL intensity), and a horizontal axis is an emission wavelength.

Two data in FIG. 7 illustrate properties of a sample EB (solid line) according to the embodiment and a sample CS (dashed line) according to the comparative example. In the active layer 30 including the 9-layered well layer 33, the pit 60 of the sample EB has the initial point between a sixth layer and a seventh layer, and is formed to penetrate the well layer 33 of the seventh layer to a ninth layer. Meanwhile, in the sample CS, the pit 60 is formed to penetrate the entire well layer 33 including all nine layers. In addition, a full width at half maximum of the GaN (102) surface by an X-ray diffraction of the sample EB is 419 seconds, and a blade-formed threading dislocation density is 1.4×10⁹ cm⁻². In addition, a full width at half maximum of the GaN (102) surface of the sample CS is 424 seconds, and a blade-formed threading dislocation density is 1.4×10⁹ cm⁻². The sample CS has substantially similar threading dislocation density as the sample EB.

As apparent in FIG. 7, across almost the entire wavelength range of light emission, the PL intensity of the sample EB is higher than the PL intensity of the sample CS. Compared to an emission peak intensity located in the vicinity of 450 nm, the PL intensity of the sample EB exceeds two times the sample CS. This may be called a synergy effect between an effect in which the area of the well layer 33 that contributes to the light emission is enlarged, and an effect in which the carrier per a unit area according to the increase of the area is reduced and the emission efficiency per unit area of the well layer 33 is improved. In the light-emitting element which uses the nitride semiconductor, a droop phenomenon in which when the injection volume of the carrier increases, the emission efficiency is deteriorated is known, and thus it is possible to reduce the carrier injection volume per unit area according to the embodiment, and to obtain the effect of improving the emission efficiency.

As the initial point 60a is in the middle of the active layer 30, and the pit 60 which is expanded in the Z direction is formed. Accordingly, it is possible to improve the emission efficiency of the active layer 30. In the light-emitting element which uses nitride semiconductor material, it is known that an effective mass of the hole h is large and the contribution of the nearest well layer to the p-type layer to the light emission is large. In other words, the well layer which is provided in the vicinity of the p-type layer 40 contributes to the light emission inside the plurality of well layers 33 included in the active layer 30. The well layer 33 which is nearest to the p-type layer 40 contributes greatly. Therefore, it is preferable that the initial point 60a of the pit 60 be formed at a position which is closer to the p-type layer 40 than one-half of the thickness in the Z direction of the active layer 30, for example. Furthermore, it is preferable that the pit 60 be formed to penetrate at least one-half of the number of the well layers among the total number of the well layers 33. It is more preferable that the pit 60 be formed to penetrate the well layer 33 which is provided at the nearest position to the p-type layer 40. By doing so, it is possible to make a larger area of a plane of the well layer 33 provided at the nearest position to the p-type layer 40, and to obtain the highly efficient light-emitting element. In addition, by including the AlGaN layer between the pit 60 and the threading dislocation 70, it is possible to further suppress the non-light-emitting recombination by the threading dislocation, and to obtain the further highly efficient light-emitting element.

In such a manner, according to the embodiment, even when the threading dislocation is present at a relatively high density, it is possible to suppress the deterioration of the emission efficiency and to obtain the highly efficient light-emitting element. In addition, it is possible to inject the hole h to the well layer through the pit 60 which is designed with an appropriate depth, and to obtain the highly efficient light-emitting element even when the threading dislocation density is large. It has generally been considered that the threading dislocation density needs to be reduced in order to obtain the highly efficient light-emitting element. However, according to the embodiment, even when the threading dislocation density is equal to or greater than 4×10⁸ cm⁻², it is possible to obtain the highly efficient light-emitting element. The X-axis full width at half maximum of the GaN (102) surface corresponding thereto is equal to or higher than 250 seconds. Particularly, if the silicon substrate is used as the substrate, the difference in the lattice constant and the difference in the thermal expansion coefficient with the gallium nitride is larger than those of the sapphire substrate, and thus there is a problem that the dislocation is likely to be generated. However, by forming the embodiment on the silicon substrate, it is possible to manufacture a highly efficient light-emitting element which has low cost and is excellent for mass production. The threading dislocation density of the nitride semiconductor formed on the silicon substrate is equal to or higher than 8×10⁸ cm⁻², for example. The X-axis full width at half maximum of the GaN (102) surface corresponding thereto is equal to or higher than 330 seconds. In this case, by applying the embodiment, it is possible to obtain a result in which the non-light-emitting recombination due to the threading dislocation is suppressed, and a result in which the emission efficiency is improved by increasing the area of the well layer that contributes to the light emission. When the diameter of the silicon substrate is equal to 8 inches or less, the effect the mass productivity is remarkably improved.

As described above, according to the embodiment, it is possible to achieve the highly efficient optical semiconductor element with suppressed impact of crystal lattice defects. For example, in the light-emitting element, such as LED, laser diode, or the like, it is possible to improve the emission efficiency of the active layer, and to achieve the light emission with high luminance. In addition, in the light-receiving element, it is possible to reduce the dark current and improve the light receiving sensitivity.

In this disclosure, “nitride semiconductor” or “nitride semiconductor material” includes a group III-V compound semiconductor of BₓIn_{y}Al_{z}Ga_{1-x-y-z}N (0≦x≦1, 0≦y≦1, 0≦z≦1, 0≦x+y+z≦1). Furthermore, a group V element even includes a mixed crystal which contains phosphorus (P), arsenic (As) or the like, in addition to nitrogen (N). Moreover, “nitride semiconductor” or “nitride semiconductor material” includes a nitride semiconductor further including various elements that are added to control various properties, such as conductivity type, and a nitride semiconductor further including various elements included without an intention, such as impurities.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An optical semiconductor element, comprising:
a first nitride semiconductor layer of a first conductivity type;
an active layer having a first surface disposed on the first nitride semiconductor layer, the active layer having a feature extending from a second surface that is parallel and opposite the first surface into the active layer; and
a second nitride semiconductor layer of a second conductivity type disposed on the second surface of the active layer and having a portion filling the feature in the active layer, wherein
the active layer has a thickness between the first nitride semiconductor layer and the portion of the second nitride semiconductor layer is greater than zero and less than a distance between the first and second surfaces.

2. The optical semiconductor element according to claim 1, wherein the feature in the active layer is a groove.

3. The optical semiconductor element according to claim 2, wherein the groove is V-shaped.

4. The optical semiconductor element according to claim 1, wherein the feature in the active layer is a plurality of grooves.

5. The optical semiconductor element according to claim 4, wherein the grooves are V-shaped.

6. The optical semiconductor element according to claim 1, wherein the feature is a pit.

7. The optical semiconductor element according to claim 6, wherein the pit is cone-shaped.

8. The optical semiconductor element according to claim 1, wherein the feature is a plurality of pits.

9. The optical semiconductor element according to claim 1, wherein the pits are cone-shaped.

10. The optical semiconductor element according to claim 1, wherein the active layer includes:
a first barrier layer at the first surface;
a second barrier layer at the second surface; and
a first well layer between the first and second barrier layers, and
the feature penetrates the first well layer.

11. The optical semiconductor element according to claim 10, wherein the first nitride semiconductor layer includes:
a second well layer between a third and a fourth barrier layer, and a bandgap of the second well layer is wider than a bandgap of the first well layer.

12. The optical semiconductor element according to claim 11, wherein
the first well layer and the second well layer comprise nitride semiconductor material including indium, and
a content ratio of indium in the first well layer is greater than a content ratio of indium in the second well layer.

13. The optical semiconductor element according to claim 1, wherein
the active layer comprises a plurality of barrier layers and a plurality of first well layers between the first and second surfaces such that at least one first well layer is between each adjacent pair of barrier layers in the plurality of barrier layers, and
the feature penetrates a first well layer from the plurality of first well layers that is nearest the second surface.

14. The optical semiconductor element according to claim 1, wherein the portion of the second nitride semiconductor layer filling the feature includes aluminum.

15. An optical semiconductor element, comprising:
a first nitride semiconductor layer of a first conductivity type;
an active layer having a first surface disposed on the first nitride semiconductor layer, the active layer having a pit or a groove extending from a second surface that is parallel and opposite the first surface into the active layer; and
a second nitride semiconductor layer of a second conductivity type disposed on the second surface of the active layer and having a portion filling the pit or groove in the active layer, wherein
the active layer has a thickness between the first nitride semiconductor layer and the portion of the second nitride semiconductor layer is greater than zero and less than a distance between the first and second surfaces.

16. The optical semiconductor element according to claim 15, wherein the active layer is a light-emitting layer comprising a plurality of first barrier layers and a plurality of first well layers between each adjacent pair of first barrier layers in the plurality of first barrier layers and the pit or groove penetrates at least one first well layer.

17. The optical semiconductor element according to claim 16, wherein
the first semiconductor layer comprises a plurality of second barrier layers and a plurality of second well layers between each adjacent pair of second barrier layers in the plurality of second barrier layers, and
a bandgap of the second well layers is wider than a bandgap of the first well layers.

18. A method of making an optical semiconductor element, the method comprising:
forming a first nitride semiconductor layer of a first conductivity type;
forming an active layer having a first surface disposed on the first nitride semiconductor layer, the active layer having a feature extending from a second surface that is parallel and opposite the first surface into the active layer; and
forming a second nitride semiconductor layer of a second conductivity type disposed on the second surface of the active layer and having a portion filling the feature in the active layer, wherein
the active layer has a thickness between the first nitride semiconductor layer and the portion of the second nitride semiconductor layer is greater than zero and less than a distance between the first and second surfaces.

19. The method according to claim 18, wherein the feature is a cone-shaped pit.

20. The method according to claim 19, wherein the feature is a V-shaped groove.
